(19) United States
(12) Patent Application Publication
(10) Pub. No.: US 2023/0273240 A1
(43) Pub. Date: Aug. 31, 2023

(54) PALLADIUM-COPPER-SILVER ALLOY

(71) Applicant: Heraeus Deutschland GmbH & Co. KG, Hanau (DE)

(72) Inventors: Jonas FECHER, Hanau (DE); Matthias WEGNER, Hanau (DE)

(21) Appl. No.: 18/172,560

(22) Filed: Feb. 22, 2023

(30) Foreign Application Priority Data
Feb. 28, 2022 (EP) 22159089.6

(51) Int. Cl. G01R 1/067; C22C 5/04; C22C 1/02; C22F 1/00; C22F 1/14

(52) U.S. Cl. CPC G01R 1/06755; C22C 5/04; C22C 1/02; C22F 1/002; C22F 1/14

(57) ABSTRACT

A palladium-copper-silver alloy consisting of 40 to 58% by weight of palladium, 25 to 42% by weight of copper, 6 to 20% by weight of silver, optionally up to 6% by weight of at least one element from the group ruthenium, rhodium, and rhenium, and up to 1% by weight of impurities, wherein the palladium-copper-silver alloy contains a crystalline phase with a B2 crystal structure and has 0% by volume to 10% by volume of precipitates of silver, palladium, and binary silver-palladium compounds. The invention also relates to a molded body, a wire, a strip, or a probe needle made of such a palladium-copper-silver alloy and to the use of such a palladium-copper-silver alloy for testing electrical contacts or for electrical contacting or for the production of a sliding contact. The invention also relates to a method for producing a palladium-copper-silver alloy.

### CROSS-REFERENCE TO RELATED APPLICATIONS

This application claims priority pursuant to 35 U.S.C. 119(a) to European Application No. EP22159089, filed Feb. 28, 2022, which application is incorporated herein by reference in its entirety.

### DESCRIPTION

The invention relates to a palladium-copper-silver alloy (PdCuAg alloy) and molded bodies made of such a palladium-copper-silver alloy, in particular a wire, a strip, or a probe needle made of such a palladium-copper-silver alloy, to the use of such a palladium-copper-silver alloy for testing electrical contacts or for electrical contacting or for the production of a sliding contact, and to a method for producing a palladium-copper-silver alloy.

During chip production, after processing, wafers are contacted directly with probe needles in order to test the functionality of integrated circuits (IC) in the unsawn state. After the structuring of the individual chips, an array of probe needles tests the semiconductor wafer for functionality. The probe needles are fixed in a probe card which is matched to the design of the wafer. In the testing process, the wafer is pressed onto the probe needles, and contact between probe needles and the pads of the ICs is produced, through a passivation layer in the case of aluminum pads. Various parameters are then tested, such as the contacting, electrical characteristics at high current density, and the electrical behavior during temperature changes.

Probe needles are thus used in the production of power electronics, the contacting of chips and other electrical circuits for testing the quality of electrical contacts (see, for example, US 2014/0266278 A1 and US 2010/0194415 A1).

The key parameters of a good probe needle are high electrical conductivity since high electrical currents have to be transmitted, and high hardness in order to keep the maintenance intervals low. Currently, metals or alloys that have a high electrical and thermal conductivity but also high hardnesses and tensile strengths are therefore used for so-called probe needles. The electrical conductivity of pure copper (100% IACS=58.1*10⁶ S/m) is used as a reference. Copper (Cu) and silver (Ag), however, cannot be used for these purposes since they are significantly too ductile and the probe needle would deform during use.

However, besides probe needles, other applications, such as, in particular, wires for sliding contacts, also benefit from materials with high electrical and thermal conductivities and at the same time good mechanical properties, such as high hardness and tensile strength. In the case of sliding contacts, it is important that, on the one hand, the surfaces cause a low transition resistance and, on the other hand, the material does not wear, i.e., is abraded or erodes, too quickly.

Applications such as probe needles or slide wires in power electronics also require high mechanical strength and hardness in addition to high electrical conductivity. In this respect, the temperature resistance or the heat resistance is also of critical importance.

Typical materials for probe needles are precipitation-hardened palladium-silver alloys that can contain 10% gold and 10% platinum and are, for example, sold under the product names Paliney® 7, Hera 6321, and Hera 648. These alloys have a high hardness of 400-500 HV. However, at 9-12% IACS, the electrical conductivity is rather low. High conductivity is a critical factor in the case of probe needles. For testing on aluminum pads, probe needles made of the materials tungsten, tungsten carbide, palladium-copper-silver alloys, and tungsten rhenium are widely used. The latter are particularly hard, wherein aluminum pads are more robust than gold pads and can better withstand testing with hard needles than gold pads can. These probe needles also do not have very high electrical conductivity. Alloys with higher electrical conductivity, such as CuAg7, are less hard (approx. 320 HV 0.05) and less heat-resistant than palladium-silver alloys or palladium-copper-silver alloys.

For use on gold pads, palladium alloys (Pd alloys) are known, such as Paliney® H3C from the company Deringer Ney or NewTec® from the company Advanced Probing. In principle, suitable palladium-copper-silver alloys are already known from U.S. Pat. No. 1,913,423 A and GB 354 216 A. Palladium-copper-silver alloy can form a structure with a superlattice, which leads to an improvement in the electrical conductivity and the mechanical stability of the alloy. The atoms in the lattice are then no longer randomly distributed, but they are ordered in periodic structures, the superlattice. As a result, hardnesses of more than 350 HV1 (Vickers hardness test according to DIN EN ISO 6507-1:2018 to −4:2018 with a test force of 9.81 N (1 kilopond)), electrical conductivities of more than 19.5% IACS, and breaking strengths of up to 1500 MPa are possible.

US 2014/377 129 A1 and U.S. Pat. No. 5,833,774 A as well as the non-prepublished European patent application with application number EP 20 19 3903 disclose hardened Ag—Pd—Cu alloys for electrical applications. Such palladium-copper-silver alloys have an electrical conductivity of about 9% to 12% IACS and a hardness of 400 to 500 HV1. A higher electrical conductivity would be desirable. U.S. Pat. No. 10,385,424 B2 discloses a palladium-copper-silver alloy additionally containing up to 5% by weight of rhenium. This palladium-copper-silver alloy is sold under the product name Paliney® 25. In this way, the electrical conductivity can be significantly increased and reaches values of more than 19.5% IACS. Rhenium has a very high melting point of 3180° C. and therefore has to be alloyed with the other metals with high effort. Oxides at the surface can restrict the function of probe needles and sliding contacts. Furthermore, a further increase in the electrical conductivity and/or the hardness of the alloy is also always desirable for the use as a material for probe needles.

In Journal of Phys. Chem. Ref. Data, Vol. 6, No 3, 1977, pages 647 to 650 summarize findings regarding the ternary phase diagram Cu—Ag—Pd. It is stated there that no ternary phase was found in the ternary system Cu—Ag—Pd. However, a binary Cu—Pd phase is mentioned, which is referred to as β′ phase and which has a body-centered cubic B2 crystal structure. The phase diagrams show that the β′ phase under standard pressure at 400° C. is thermodynamically stable up to a silver content of 4% by weight, wherein with a higher silver content, the PdCuAg alloy forms a heterogeneous phase mixture with silver-palladium precipitates. The maximum hardness is assumed with a composition of 25% by weight of Cu, 25% by weight of Ag, and 50% by weight of Pd or with a composition of 30% by weight of Cu, 30% by weight of Ag, and 40% by weight of Pd.

The object of the invention is therefore to overcome the disadvantages of the prior art. In particular, an alloy and a molded body, a wire, a strip, or a probe needle are to be provided, which have a high electrical conductivity with at the same time high hardness, but which are at the same time simple to produce and have the highest possible oxidation resistance on the surface. If possible, the molded body should be producible more cost-effectively than comparable alloys. The alloy and the products should be usable as probe needles for testing electrical contacts.

The aim of the invention is thus to find an alloy, such as the known palladium-copper-silver alloys, that combines the mechanical properties (hardness, yield strength, spring properties) of the known palladium-copper-silver alloy with a higher electrical conductivity. Such palladium-copper-silver alloys have a critical technical advantage, in particular when used as a material for probe needles.

A further object of the invention is to provide a molded body, in particular a wire, a strip, or a probe needle, which fulfills the aforementioned properties. Furthermore, a further object is the development of a wire for a sliding contact having multiple wires made of such an alloy.

The objects of the invention are achieved by a palladium-copper-silver alloy consisting of
(a) 40 to 58% by weight of palladium,
(b) 25 to 42% by weight of copper,
(c) 6 to 20% by weight of silver,
(d) optionally up to 6% by weight of at least one element selected from the group consisting of ruthenium, rhodium, and rhenium, and
(e) up to 1% by weight of impurities,

wherein the palladium-copper-silver alloy contains a crystalline phase with a B2 crystal structure, and

wherein the palladium-copper-silver alloy has 0% to 10% by volume of precipitates of silver, palladium, and binary silver-palladium compounds.

The sum of the elements ruthenium, rhodium, and rhenium may not exceed a weight proportion 35 of 6% by weight in the palladium-copper-silver alloy.

The proportions of palladium, copper, and silver, and also the optional proportions of ruthenium, rhodium, and/or rhenium and/or the impurities add up to 100% by weight.

It is also possible for none of the elements selected from the list ruthenium, rhodium, and rhenium to be contained in the palladium-copper-silver alloy. The palladium-copper-silver alloy then consists of the specified proportions of palladium, copper, silver, and up to 1% by weight of impurities.

The specification of the proportion of precipitates in % by volume means that the sum of the precipitates of silver and the precipitates of palladium and the precipitates of binary silver-palladium compounds is at most the specified volume proportion of 10% by volume. According to the invention, it is also possible for no precipitates of silver, palladium, or binary silver-palladium compounds to be contained in the palladium-copper-silver alloy. Only a proportion of more than 10% by volume of these precipitates in total is ruled out. The precipitates can consist of silver or palladium or of binary silver-palladium compounds, but the sum of all of these precipitates (silver, palladium, and binary silver-palladium compounds) must not exceed a proportion of 10% by volume. The silver, the palladium, and the binary silver-palladium compounds of the precipitates must contain no more than 5% by weight of copper and no more than 1% by weight of other metals, preferably no more than 2% by weight of copper. The proportion of silver, palladium, or binary silver-palladium compounds in the palladium-copper-silver alloy can be determined experimentally using a scanning electron microscope (SEM) in phase contrast (measurement of secondary electrons) by a quantitative analysis of the area proportions of an SEM image of a sufficiently polished transverse section. Such methods are known to the person skilled in the art. The proportion can also be determined by means of EDX mapping (likewise by an evaluation of the area proportions of the measured section). Further possibilities for measurement are available and applicable.

It is preferred according to the invention that at most 1% by weight of rhenium is contained in the palladium-copper-silver alloy, particularly preferably at most 0.8% by weight of rhenium is contained in the palladium-copper-silver alloy.

The palladium-copper-silver alloy containing a crystalline phase with a B2 crystal structure means that the crystalline phase with the B2 crystal structure in the palladium-copper-silver alloy must be detectable at least locally with X-ray diffractometry or with electron diffraction images. Used for detection are, in particular, electron diffraction images of the palladium-copper-silver alloy, which show the reflections and diffraction patterns that are typical of the B2 crystal structure and which can be clearly distinguished from electron diffraction images of other crystal structures occurring in the palladium-copper-silver alloy. With larger proportions of the B2 crystal structure (more than 1% by volume), the B2 crystal structure can also be detected by means of XRD by X-ray diffractometry of suitably prepared surfaces and powders of the palladium-copper-silver alloy. Other methods for detecting the B2 crystal structure in the palladium-copper-silver alloy are conceivable.

An impurity is understood to mean chemical elements that occur in the metals of the alloy as usual impurities and, for preparation-related reasons, cannot be removed or can only be removed with great effort. Usual impurities can be different depending on the manufacturer and extraction.

The designation B2 denotes a space group according to the Strukturbericht notation. The B2 crystal structure, or B2 structure for short, is an intermetallic structure of the CsCl type and is a body-centered cubic (bcc) lattice structure. The B2 crystal structure has a space group Pm3̅m in Hermann-Mauguin notation. In the binary system Pd—Cu, this crystalline phase is also referred to as β′ phase. One type of atom (e.g., Pd) is located at the corners (8×⅛ atom per unit cell) and (at least) another type of atom (e.g., copper and silver) is located in the center (1×1 atom per unit cell), resulting in an atomic ratio of 1:1. There may be slight deviations from the exact mixture. Such a B2 crystal structure occurs with CsCl, but also with NiAl or even with ordered binary PdCu.

The B2 crystal structure can be determined by suitable microscopic examinations or TEM examinations of samples prepared appropriately for TEM examinations (e.g., by means of FIB (focused ion beam)) or also at least roughly by quantitative X-ray diffraction examinations (XRD examinations) of volume bodies of the palladium-copper-silver alloy or also of powders of the palladium-copper-silver alloy. Such methods are known to the person skilled in the art. A Bragg-Brentano diffractometer was used for the XRD measurement, wherein a measurement range (2Theta) of 10-115 was recorded with a step size of 0.050 at a measurement time of 96 s/step, and a copper X-ray source with 40 kV and 40 mA was used as X-ray source. Surprisingly, the crystalline phase with the B2 crystal structure also occurs with higher silver contents than would have been expected on the basis of the known examinations. At the same time, palladium-copper-silver alloys with this crystalline phase with the B2 crystal structure also have particularly advantageous physical properties for the applications according to the invention.

The palladium-copper-silver alloy is preferably suitable for producing probe needles and/or sliding contacts.

It may also be provided that the palladium-copper-silver alloy contains
(a) 41 to 56% by weight of palladium,
(b) 26 to 42% by weight of copper, and
(c) 7 to 19% by weight of silver,

preferably
(a) 41 to 56% by weight of palladium,
(b) 26 to 42% by weight of copper, and
(c) 8 to 18% by weight of silver,

more preferably
(a) 41 to 56% by weight of palladium,
(b) 26 to 42% by weight of copper, and
(c) 9 to 18% by weight of silver,

even more preferably
(a) 41 to 56% by weight of palladium,
(b) 26 to 42% by weight of copper, and
(c) 10 to 18% by weight of silver.

At higher minimum silver proportions, a larger proportion of the B2 crystal structure and no or surprisingly small proportions (up to 10% by volume) of precipitates of silver, palladium, and binary silver-palladium compounds were surprisingly found than would have been expected on the basis of the examinations known from the prior art. In addition, advantageous physical property combinations result.

Furthermore, it may be provided that the palladium-copper-silver alloy contains
(a) 41 to 56% by weight of palladium,
(b) 26 to 42% by weight of copper, and
(c) 6 to 18% by weight of silver,

preferably
(a) 41 to 56% by weight of palladium,
(b) 26 to 42% by weight of copper, and
(c) 6 to 16% by weight of silver,

more preferably
(a) 41 to 56% by weight of palladium,
(b) 26 to 42% by weight of copper, and
(c) 6 to 14% by weight of silver.

It may be provided that the palladium-copper-silver alloy contains
(a) 41 to 56% by weight of palladium,
(b) 26 to 42% by weight of copper, and
(c) 7 to 18% by weight of silver,

preferably
(a) 41 to 56% by weight of palladium,
(b) 26 to 42% by weight of copper, and
(c) 8 to 17% by weight of silver,

more preferably
(a) 41 to 56% by weight of palladium,
(b) 26 to 42% by weight of copper, and
(c) 9 to 16% by weight of silver,

even more preferably
(a) 41 to 56% by weight of palladium,
(b) 26 to 42% by weight of copper, and
(c) 10 to 15% by weight of silver.

According to the invention, it may furthermore be provided that the palladium-copper-silver alloy has a weight ratio of palladium to copper of at least 1.05 and at most 1.6 and has a weight ratio of palladium to silver of at least 3 and at most 6.

A weight ratio of palladium to copper of at least 1.05 and at most 1.6 means that the palladium is contained in the palladium-copper-silver alloy with a weight of at least 105% and at most 160% of the weight of the copper contained in the palladium-copper-silver alloy.

Accordingly, a weight ratio of palladium to silver of at least 3 and at most 6 means that the palladium is contained in the palladium-copper-silver alloy with a weight of at least three times and at most six times the weight of the silver contained in the palladium-copper-silver alloy.

It may be provided that the palladium-copper-silver alloy has a weight ratio of palladium to copper of at least 1.2 and at most 1.55, preferably a weight ratio of palladium to copper of at least 1.3 and at most 1.5, particularly preferably a weight ratio of palladium to copper of at least 1.35 and at most 1.45, more particularly preferably a weight ratio of palladium to copper of 1.41.

These weight ratios provide palladium-copper-silver alloys with particularly high electrical conductivity.

It may be provided that the palladium-copper-silver alloy has a weight ratio of palladium to silver of at least 3.5 and at most 5.5, preferably a weight ratio of palladium to silver of at least 4 and at most 5.5, particularly preferably a weight ratio of palladium to silver of at least 4.6 and at most 5.2, more particularly preferably a weight ratio of palladium to silver of 4.9.

These weight ratios also provide palladium-copper-silver alloys with particularly high electrical conductivity.

It may be provided that the palladium-copper-silver alloy has a weight ratio of palladium to copper of at least 1.2 and at most 1.55 and a weight ratio of palladium to silver of at least 3.5 and at most 5.5, preferably a weight ratio of palladium to copper of at least 1.3 and at most 1.5 and a weight ratio of palladium to silver of at least 4 and at most 5.5, particularly preferably a weight ratio of palladium to copper of at least 1.35 and at most 1.45 and a weight ratio of palladium to silver of at least 4.6 and at most 5.2, more particularly preferably a weight ratio of palladium to copper of 1.41 and a weight ratio of palladium to silver of 4.9.

These weight ratios also provide palladium-copper-silver alloys with particularly high electrical conductivity.

Furthermore, it may be provided that the palladium-copper-silver alloy contains at least 0.1% by weight of at least one element selected from the group consisting of ruthenium, rhodium, and rhenium.

It may be provided that the palladium-copper-silver alloy contains at least 1% by weight of at least one element selected from the group consisting of ruthenium, rhodium, and rhenium.

It may be provided that the palladium-copper-silver alloy contains at least 1.5% by weight of at least one element selected from the group consisting of ruthenium, rhodium, and rhenium.

It may also be provided that the palladium-copper-silver alloy contains at most 5% by weight of at least one element selected from the group consisting of ruthenium, rhodium, and rhenium, preferably at most 4% by weight of at least one element selected from the group consisting of ruthenium, rhodium, and rhenium, particularly preferably at most 3% by weight of at least one element selected from the group consisting of ruthenium, rhodium, and rhenium.

The sum of the elements ruthenium, rhodium, and rhenium may not exceed a weight proportion in the palladium-copper-silver alloy of 5% by weight, preferably a weight proportion in the palladium-copper-silver alloy of 4% by weight, particularly preferably a weight proportion in the palladium-copper-silver alloy of 3% by weight.

It may be provided that the palladium-copper-silver alloy contains at least 0.1% by weight and at most 5% by weight of at least one element selected from the group consisting of ruthenium, rhodium, and rhenium, preferably at least 1% by weight and at most 4% by weight of at least one element selected from the group consisting of ruthenium, rhodium, and rhenium, particularly preferably at least 1% by weight and at most 3% by weight of at least one element selected from the group consisting of ruthenium, rhodium, and rhenium.

The sum of the elements ruthenium, rhodium, and rhenium may not exceed a weight proportion in the palladium-copper-silver alloy of 5% by weight, preferably a weight proportion in the palladium-copper-silver alloy of 4% by weight, particularly preferably a weight proportion in the palladium-copper-silver alloy of 3% by weight.

The alloy containing more than 0.1% by weight and at most 5% by weight of at least one element selected from the group consisting of ruthenium, rhodium, and rhenium means that the sum of the weight proportions of the at least one element of the group constitutes more than 0.1% by weight and at most 5% by weight of the weight of the entire alloy. The alloy containing more or less or exactly X % by weight of rhenium, ruthenium, and/or rhodium in general means that the sum of the weight proportions of rhenium, ruthenium, and/or rhodium constitutes the corresponding percentage of X % by weight of the weight of the entire alloy.

Furthermore, it may be provided that the palladium-copper-silver alloy contains up to 1% by weight of rhenium, wherein the palladium-copper-silver alloy preferably contains less than 0.1% by weight of rhodium, particularly preferably the palladium-copper-silver alloy contains more than 1% by weight and at most 2% by weight of ruthenium and between 0.1% by weight and 1% by weight of rhenium, more particularly preferably at least 1.1% by weight and at most 1.5% by weight of ruthenium and between 0.2% by weight and 0.8% by weight of rhenium, especially preferably 1.1% by weight of ruthenium and 0.4% by weight of rhenium.

The palladium-copper-silver alloy here preferably contains more than 1% by weight and at most 6% by weight of ruthenium.

These palladium-copper-silver alloy(s) surprisingly have a particularly high experimental electrical conductivity of at least 25% IACS (14.5*10⁶ S/m) with simultaneously high hardness of 365 HV1. Ruthenium-rhenium precipitates at the grain boundaries of the palladium-copper-silver alloy are presumably responsible for this.

Furthermore, it may be provided that the palladium-copper-silver alloy contains precipitates of ruthenium, rhodium, rhenium, or a mixture of two of the elements selected from ruthenium, rhodium, and rhenium, or a mixture of ruthenium, rhodium, and rhenium, wherein preferably at least 90% by volume of the precipitates are arranged at grain boundaries of the palladium-copper-silver alloy, particularly preferably at least 99% by volume of the precipitates are arranged at grain boundaries of the palladium-copper-silver alloy.

This increases the mechanical properties, such as the breaking strength and the deformation resistance. As a result, the palladium-copper-silver alloy can be used better as a probe needle.

It may also be provided that the impurities in total have a proportion of at most 0.9% by weight in the palladium-copper-silver alloy, preferably a proportion of at most 0.1% by weight in the palladium-copper-silver alloy.

This ensures that the physical properties of the palladium-copper-silver alloy are not influenced or are influenced as little as possible by the impurities.

A mixture of multiple elements is preferably understood to mean a mixture in which at least 0.1% by weight of all of these elements are contained in the palladium-copper-silver alloy.

It may also be provided that the palladium-copper-silver alloy contains up to 6% by weight of at least one element selected from the group consisting of ruthenium and rhodium, preferably from 0.1% by weight to 6% by weight of at least one element selected from the group consisting of ruthenium and rhodium, particularly preferably from 1% by weight to 6% by weight of at least one element selected from the group consisting of ruthenium and rhodium.

It may be provided that the palladium-copper-silver alloy contains at least 1% by volume of the crystalline phase with a B2 crystal structure, preferably at least 2% by volume of the crystalline phase with a B2 crystal structure, particularly preferably at least 5% by volume of the crystalline phase with a B2 crystal structure.

Furthermore, it may be provided that the crystalline phase with the B2 crystal structure has a silver content of at least 6% by weight.

The formation of the crystalline phase with the B2 crystal structure with these silver contents is surprising, in particular in the case of temperature treatments at temperatures of at most 500° C. or even less than 400° C.

It may be provided that the crystalline phase with the B2 crystal structure has a silver content of at least 7% by weight, preferably a silver content of at least 8% by weight, particularly preferably a silver content of at least 9% by weight, more particularly preferably a silver content of at least 10% by weight.

It may be provided that the crystalline phase with the B2 crystal structure has at least 40% by weight and at most 58% by weight of palladium and at least 25% by weight and at most 42% by weight of copper, preferably at least 41% by weight and at most 56% by weight of palladium and at least 26% by weight and at most 42% by weight of copper.

It may be provided that the crystalline phase with the B2 crystal structure is produced by a temperature treatment, preferably by tempering at a temperature between 250° C. and 500° C. for a period of at least 1 minute, wherein, particularly preferably, after the tempering, the palladium-copper-silver alloy is not subjected to any further temperature treatment at a temperature of more than 500° C.

It may be provided that the crystalline phase with the B2 crystal structure is produced by annealing at a temperature between 300° C. and 450° C. for a period of at least 2 minutes, the crystalline phase with the B2 crystal structure is preferably produced by annealing at a temperature between 300° C. and 450° C. for a period of at least 2 minutes, the crystalline phase with the B2 crystal structure is particularly preferably produced by annealing at a temperature between 300° C. and 450° C. for a period of at least 2 minutes, the crystalline phase with the B2 crystal structure is more particularly preferably produced by annealing at a temperature between 350° C. and 400° C. for a period of at least 3 minutes.

The crystalline phase with the B2 crystal structure is preferably not produced by a temperature treatment at 375° C. to 385° C. for 1 h to 2 h, is particularly preferably not produced by a temperature treatment at 380° C. for 1.5 h.

It may also be provided that the crystalline phase with the B2 crystal structure is obtained by quenching the palladium-copper-silver alloy after a temperature treatment, in particular after tempering, or after annealing.

The quenching preferably takes place over a temperature range of at least 250° C. at a cooling rate of at least 10° C. per second.

Furthermore, it may be provided that the palladium-copper-silver alloy is shaped and hardened by multiple heat treatments and multiple rollings, wherein the heat treatments preferably take place at a temperature between 700° C. and 950° C. and quenching takes place after the heat treatment, wherein no melting of the palladium-copper-silver alloy takes place during the heat treatment.

The quenching preferably takes place over a temperature range of at least 400° C. at a cooling rate of at least 10° C. per second.

Furthermore, it may be provided that the palladium-copper-silver alloy is produced by melting metallurgy and is subsequently hardened by rolling and tempering, wherein the palladium-copper-silver alloy preferably has a hardness of at least 380 HV0.05.

As a result, the hardness of the palladium-copper-silver alloy can be improved.

It may be provided that the palladium-copper-silver alloy has a hardness of at least 380 HV0.05.

It may be provided that the palladium-copper-silver alloy has an electrical conductivity of at least 22% IACS (12.8*10⁶ S/m), preferably an electrical conductivity of at least 25% IACS (14.5*10⁶ S/m), particularly preferably an electrical conductivity of at least 26% IACS (15.1*10⁶ S/m).

It may be provided that the palladium-copper-silver alloy has a tensile strength of at least 1300 MPa.

Palladium-copper-silver alloys with these physical properties are possible with the additions according to the invention of ruthenium and rhodium and are particularly suitable for the production of probe needles.

It may preferably also be provided that the palladium-copper-silver alloy has a mean grain size of at most 2 μm.

It may preferably be provided that the palladium-copper-silver alloy has a mean grain size of at most 1.5 μm, preferably a mean grain size of at most 1 μm.

It may particularly preferably be provided that the palladium-copper-silver alloy has a mean grain size of at least 0.01 μm, preferably a mean grain size of at least 0.05 μm, particularly preferably a mean grain size of at least 0.1 μm.

The mean grain size is determined according or analogously to DIN EN ISO 643:2019, corrected version 2020-03/German version ISO 643:2020 from June 2020, wherein the mean value of line cut segments of a transverse section is determined. The sample preparation takes place as described in the standard, even though in the present case, the palladium-copper-silver alloy is not a steel. The etching method can be adapted to the chemical resistance of the palladium-copper-silver alloy so that the grain boundaries of the grains of the palladium-copper-silver alloy are visible as well as possible. If the palladium-copper-silver alloy was rolled during production, the transverse section to be examined is cut parallel to the force exerted by the rollers, and ground and polished.

It may be provided that the palladium-copper-silver alloy has a mean grain size of at least 0.01 μm and at most 2 μm, preferably a mean grain size of at least 0.05 μm and at most 1.5 μm, particularly preferably a mean grain size of at least 0.1 μm and at most 1 μm.

It may be provided that the palladium-copper-silver alloy has a mean grain size of at least 0.01 μm and at most 2 μm, preferably a mean grain size of at least 0.05 μm and at most 2 μm, particularly preferably a mean grain size of at least 0.1 μm and at most 2 μm.

It may be provided that the palladium-copper-silver alloy has a mean grain size of at least 0.1 μm and at most 2 μm, preferably a mean grain size of at least 0.1 μm and at most 1.5 μm, particularly preferably a mean grain size of at least 0.1 μm and at most 1 μm.

According to a preferred development, it may be provided that the palladium-copper-silver alloy has less than 5% by volume of precipitates of silver, palladium, and binary silver-palladium compounds, preferably less than 2% by volume of precipitates of silver, palladium, and binary silver-palladium compounds, particularly preferably less than 1% by volume of precipitates of silver, palladium, and binary silver-palladium compounds, more particularly preferably no precipitates of silver, palladium, and binary silver-palladium compounds. The specification of the proportion in % by volume means that the sum of the precipitates of silver and the precipitates of palladium and the precipitates of binary silver-palladium compounds is below the specified volume proportion.

This achieves a high electrical conductivity with simultaneously high breaking strength of the palladium-copper-silver alloy.

It may also be provided that the palladium-copper-silver alloy has less than 5% by volume of silver precipitates, preferably less than 2% by volume of silver precipitates, particularly preferably less than 1% by volume of silver precipitates.

A silver precipitate is understood in the present case to mean a precipitate which consists of at least 95% by weight of silver, preferably at least 99% by weight of silver.

It may also be provided that the palladium-copper-silver alloy has less than 5% by volume of palladium precipitates, preferably less than 2% by volume of palladium precipitates, particularly preferably less than 1% by volume of palladium precipitates.

A palladium precipitate is understood in the present case to mean a precipitate which consists of at least 95% by weight of palladium, preferably at least 99% by weight of palladium.

It may also be provided that the palladium-copper-silver alloy has less than 5% by volume of silver-palladium precipitates, preferably less than 2% by volume of silver-palladium precipitates, particularly preferably less than 1% by volume of silver-palladium precipitates.

A silver-palladium precipitate is understood in the present case to mean a precipitate which consists of at least 95% by weight of silver and palladium, preferably at least 99% by weight of silver and palladium.

The objects underlying the present invention are also achieved by a molded body consisting of a previously described palladium-copper-silver alloy, wherein the molded body preferably has the shape of a general cylinder with any base or of a coil-like general cylinder with any base, wherein particularly preferably, the height of the general cylinder is greater than all dimensions of the base of the general cylinder, wherein more particularly preferably, a minimum cross section of the base is at most 500 μm and a maximum cross section of the base is at most 10 mm.

The molded body can be coated at least in regions on its surfaces.

The molded body thus has a cylindrical geometry (the shape of a general cylinder, except for a few as a result of the production where applicable). The general cylindrical shape is particularly well suited for further processing as a wire piece or strip piece. Geometrically, a shape of a general cylinder is understood to mean a cylinder with any base, i.e., not only a cylinder with a circular base. The radial lateral surface of the molded body can thus be realized by the cylinder jacket of a cylinder with any base, in particular with differently shaped bases, i.e., also with non-circular and non-round bases, for example with a rectangular or oval base. However, according to the invention, a cylindrical geometry with a rotationally symmetrical and in particular circular base or with a wide rectangular base for the molded body is preferred since a wire with a round or circular cross section or a flat strip with a rectangular cross section is the simplest to process further. In the embodiment as a strip, it is preferred that the base of the general cylinder has a width that is at least 5 times greater than the thickness of the base of the general cylinder, particularly preferably that the base of the general cylinder has a width that is at least 20 times greater than the thickness of the base of the general cylinder, more particularly preferably that the base of the general cylinder has a width that is at least 50 times greater than the thickness of the base of the general cylinder.

The minimum cross section is defined as the distance between two parallel tangents of a surface (here of the edge of the base of the general cylinder), wherein the tangents with the smallest possible distance are selected. The maximum cross section is defined as the distance between two parallel tangents of a surface (here of the edge of the base of the general cylinder), wherein the tangents with the greatest possible distance are selected. In the case of round bases, this definition corresponds to the measuring principle of a measuring slide but deviates therefrom in the case of constrictions.

Wires, strips, and probe needles made of such palladium-copper-silver alloys are particularly well suited for electrical contact measurements due to their high hardness, elasticity, and electrical conductivity.

It may be provided that the molded body is a wire or a strip, wherein the wire or the strip is preferably wound as a coil. Strictly speaking, the molded body is then no longer exactly cylindrical but a body obtained from a cylinder. However, in the sense of the present invention, such geometries are still to be understood as cylinders, even with such deviations. The geometric specifications are thus not to be understood as mathematically exact.

The objects underlying the present invention are also achieved by a probe needle or a sliding contact wire consisting of a previously described palladium-copper-silver alloy, wherein the probe needle or the sliding contact wire preferably has, at least in sections, the shape of a general cylinder with any base or of a curved general cylinder with any base, wherein particularly preferably, a minimum cross section of the base is at most 500 μm and a maximum cross section of the base is at most 10 mm, and/or the probe needle is attached to a card and electrically contacted at one end and the other end is mounted in a freely floating manner, or the sliding contact wire is attached to an electrical contact and electrically contacted at one end and the other end is mounted in a freely floating manner.

The objects underlying the present invention are also achieved by the use of such a palladium-copper-silver alloy or of such a molded body or of a part of such a molded body or for testing electrical contacts or for electrical contacting or for producing a sliding contact.

For these applications, the palladium-copper-silver alloy according to the invention and the molded bodies, wires, strips, and probe needles produced therefrom are particularly well suited.

The objects underlying the present invention are also achieved by a method for producing a palladium-copper-silver alloy, characterized by the chronological steps of:
A) optionally prealloying palladium with at least one of the elements selected from the list ruthenium, rhodium, and rhenium, with a molar ratio of palladium to the at least one element selected from the list ruthenium, rhodium, and rhenium of at least 3:1, by melting to produce a palladium prealloy;
B) alloying palladium or the palladium prealloy with copper and silver by melting and solidification in vacuo and/or under a protective gas, wherein at least 40% by weight and at most 58% by weight of palladium or at least 40% by weight and at most 64% by weight of palladium prealloy, at least 25% by weight and at most 42% by weight of copper and at least 6% by weight and at most 20% by weight of silver are weighed out;
C) repeated processing by annealing at a temperature of more than 750° C. for at least 10 minutes and subsequent quenching and subsequent rolling;
D) rolling to achieve a final thickness of at most 100 μm;
E) final annealing at a temperature between 250° C. and 600° C. for a period of at least 1 minute.

When the melting and solidification take place in vacuo and under a protective gas, at least a portion of the heating of the metals preferably takes place under vacuum, while the melting and solidification takes place under a protective gas.

The annealing in step C) must take place at a temperature below the melting temperature of the palladium-copper-silver alloy.

When the palladium prealloy is weighed out, care must be taken in the determination of the weighed portion of the palladium that the palladium content in the palladium prealloy is less than 100% by weight. Accordingly, a larger weight proportion of the palladium prealloy must accordingly be weighed out in order to achieve the desired weighed portion of palladium. The proportion of the at least one element selected from the list ruthenium, rhodium, and rhenium results automatically and must consequently already be set during the production of the palladium prealloy in step A).

It may be provided that in step B), a weight ratio of palladium to copper of at least 1.05 and at most 1.6 and a weight ratio of palladium to silver of at least 3 and at most 6 are weighed out.

Furthermore, it may be provided that the melting in step B) takes place by induction melting or by vacuum induction melting.

Furthermore, it may be provided that in step B), a noble gas, in particular argon, is used as protective gas, preferably at a partial pressure between 10 mbar and 100 mbar.

It may also be provided that in step B), the solidification is carried out by casting in a copper permanent mold, in particular in an uncooled copper permanent mold, wherein the temperature of the melt before casting is preferably less than 100° C. above the melting temperature of the palladium-copper-silver alloy.

Furthermore, it may be provided that the quenching in step C) is carried out in water.

It may also be provided that the annealing in step C) is carried out at a temperature between 850° C. and 950° C., preferably at a temperature of 900° C.

Furthermore, it may be provided that the final annealing in step E) takes place at a temperature between 300° C. and 450° C., preferably at a temperature between 360° C. and 400° C.

It may be provided that in step C), the annealing takes place for a period of between 0.5 h and 2 h and/or the annealing is carried out in a reducing atmosphere, in particular under carbon monoxide.

It may also be provided that a reshaping between 10% and 80%, preferably a reshaping between 40% and 60%, takes place during rolling in step C).

A reshaping of X % means that during rolling, a cross section of the palladium-copper-silver alloy is reduced to at least X % of the cross section.

It may be provided that in step E), the final annealing takes place for a period of at least 1 minute, preferably for a period of at least 2 minutes, particularly preferably for a period of at least 5 minutes.

The final annealing in step E) preferably takes place not by a temperature treatment at 375° C. to 385° C. for 1 h to 2 h, particularly preferably not by a temperature treatment at 380° C. for 1.5 h.

It may be provided that in step A), the prealloying is carried out in a reducing atmosphere, preferably in a CO atmosphere.

The invention is based on the surprising finding that the palladium-copper-silver alloys according to the invention with the B2 crystal structure are also formed with surprisingly high silver contents, without larger amounts (more than 10% by volume) of silver, palladium, and binary silver-palladium compounds being produced as precipitates. With such palladium-copper-silver alloys, a high electrical conductivity can be combined with a high hardness. At the same time, the palladium-copper-silver alloys are uncomplicated to produce. The molded bodies, wires, strips, sliding contacts, and probe needles produced from the alloys according to the invention have the corresponding advantageous properties. It could not be expected from the prior art and from the examinations regarding the ternary Cu—Ag—Pd phase diagram that an alloy with the B2 crystal structure and without precipitates of silver, palladium, and binary silver-palladium compounds is obtained even with high silver contents, which alloy leads to the surprisingly advantageous physical property combinations which are advantageous in such a manner for probe needles and sliding contacts.

It was even possible to achieve electrical conductivities of 27% and 28% IACS when a palladium-copper-silver alloy with ruthenium is produced and measured. A surprisingly high hardness could be achieved.

With the present invention, electrical conductivities of 27% IACS or even more are possible. 100% IACS correspond to 58 m/(ohm mm²).

The use of ruthenium or rhodium as an alloy component of palladium-copper-silver alloys is surprising in comparison to the use of rhenium due to the different chemical properties of these elements.

Compared to rhenium, rhodium and ruthenium are located both in a different main group and in a different period of the periodic table, which, in a first approximation, implies very different properties and different alloying behavior. Rhodium and ruthenium are platinum group metals, while rhenium belongs to the manganese group, which is why no property similarity is to be expected. Rhenium has a hexagonal crystal structure while rhodium is face-centered cubic.

Ruthenium has a lower solubility in silver than rhenium (2.65×10⁻⁴ for ruthenium compared to 1.44×10⁻³ for rhenium). This should have a positive effect on the electrical conductivity of the palladium-copper-silver alloy according to the invention. In addition, ruthenium precipitates at the grain boundaries were found in electron-microscopic examinations in palladium-copper-silver alloys with 1.1% by weight to 1.5% by weight of ruthenium. They can lead to a greater hardness of the palladium-copper-silver alloy by precipitation hardening.

The palladium-copper-silver alloy according to the invention with the B2 crystal structure is characterized by a high hardness, good spring properties, and at the same time good electrical conductivity. It is therefore predestined for use as a material for the production of probe needles. The incorporation of larger proportions of silver into the superstructure of the B2 crystal structure appears to have improved the electrical conductivity of the palladium-copper-silver alloy, wherein, with such silver contents, no or only small proportions of the B2 crystal structure could be expected. In particular, the silver-palladium precipitates, which would actually have been expected in the palladium-copper-silver alloy, are surprisingly missing, as a result of which the hardness and the spring properties of the corresponding palladium-copper-silver alloy are better than would actually have been expected on the basis of the findings from the prior art regarding the ternary Cu—Ag—Pd phase diagram.

In the case of a weight ratio (of 1.05 to 1.6) of palladium and copper, the palladium-copper-silver alloy with the B2 crystal structure with a small mean grain size can be set by corresponding heat treatment and rolling out thin. The ordered B2 crystal structure of the palladium and copper atoms, together with the small mean grain size, results in both the hardness and the electrical conductivity of the palladium-copper-silver alloy increasing. The addition of silver in the ratio of palladium to silver enables an additional increase in strength by precipitation hardening. The addition of ruthenium, rhodium, rhenium, or mixtures thereof in the order of 1% by weight to 6% by weight and the rolling out to form thin layers surprisingly contribute to the formation of a particularly low mean grain size of the palladium-copper-silver alloy with the B2 crystal structure, which positively influences hardness and reshapability of the palladium-copper-silver alloy. In addition, the ruthenium, rhodium, rhenium, or the mixture thereof, which are presumably preferably arranged at the grain boundaries, prevents grain growth and creep at the operating temperature. This results in a longer durability of the probe needles manufactured therefrom. At 27% to 30% IACS with a hardness of more than 400 HV, the electrical conductivity achieved is particularly well suited for use as a probe needle. The physical properties of the palladium-copper-silver alloy according to the invention with ruthenium are thus also better with respect to electrical conductivity and hardness than those of Paliney® 25 from the company Deringer Ney.

Exemplary embodiments of the invention are explained below, but without limiting the invention.

The palladium-copper-silver alloys described below were produced by first producing prealloys by induction melting. The prealloys produced were palladium-ruthenium, palladium-rhenium, and palladium-rhodium prealloys. Due to the elements palladium, ruthenium, and rhodium having melting temperatures and densities that do not deviate too strongly from one another, the production of the prealloys is cost-effectively possible without any problems and without great effort.

These prealloys were subsequently alloyed with copper and silver by vacuum induction melting.

The melting crucible is charged cold, the vacuum chamber is closed and pumped down until the dew point is −55° C. or below. Meanwhile, the material is preheated but not yet melted. When the dew point is reached (after about 30 min), an argon partial pressure of 50 mbar is applied to the vacuum chamber, and the material is melted. The partial pressure is necessary to prevent the silver from evaporating, which would change the alloy composition. The casting takes place relatively cold (approx. 50 K above the melting point of the alloy) into an uncooled Cu permanent mold. The casting skin of the ingot can be removed by milling or also in some other way.

Subsequently, the ingots thus melted are shaped and hardened by heat treatments and rolling. For this purpose, the ingots were tempered twice for 60 minutes and once for 45 minutes at 900° C. in a CO atmosphere and quenched in water. In between, reshaping by 60% and by a further 50% by means of rolling took place. Further such annealing and rolling steps take place subsequently. Wherein, as the last step, the material is rolled at 20 μm to 100 μm and subsequently stored at 380° C. for at least 4 minutes, as a result of which a hardening effect occurs and good electrical conductivity is achieved.

Subsequently, the electrical conductivity was determined with a four-point measurement. The four-point measurement method, also referred to as four-point measurement or four-tip measurement, is a method for determining the sheet resistance, i.e., the electrical resistance of a surface or thin layer. In the method, four measuring tips are brought in a row onto the surface of the foil, wherein a known current flows over the two outer measuring tips and the potential difference, i.e., the electrical voltage between the two inner measuring tips, is measured with these two inner measuring tips. Since the method is based on the principle of the four-conductor measurement, it is largely independent of the transition resistance between the measuring tips and the surface (Thomson bridge principle). Adjacent measuring tips respectively have the same distance. The sheet resistance R results from the measured voltage U and the current I according to the formula:

$$R = \frac{π}{ln 2} \frac{U}{I}$$

In order to calculate the specific resistance p of the layer material from the sheet resistance R, the sheet resistance is multiplied by the thickness d (layer thickness) of the foil:

ρ=dR

The electrical conductivity results from the reciprocal of the specific resistance.

The hardness is carried out according to HV0.05, Vickers hardness test according to DIN EN ISO 6507-1:2018 to -4:2018 with a test force of 0.490 N (0.05 kilopond). The strength was examined by means of tensile tests, and the microstructure was examined by means of metallographic sections.

The mean grain size is determined according or analogously to DIN EN ISO 643:2019, corrected version 2020-03/German version ISO 643:2020 from June 2020, wherein the mean value of line cut segments of a transverse section is determined. The sample preparation takes place as described in the standard, even though in the present case, the palladium-copper-silver alloy is not a steel. The etching method can be adapted to the chemical resistance of the palladium-copper-silver alloy so that the grain boundaries of the grains of the palladium-copper-silver alloy are visible as well as possible. If the palladium-copper-silver alloy was rolled during production, the transverse section to be examined is cut parallel to the force exerted by the rollers, and ground and polished.

For the preparation of the sample for transmission electron microscope examinations (TEM examinations), a Zeiss Crossbeam 540 XB (Zeiss GmbH, Oberkochen, Germany) was used, combined with a Gemini2 electron column and with a Capella focused ion beam (FIB) with Ga+ ions. For the examination, the samples were prepared by first applying a 2 μm thick Pt protective layer to the surface. Then, in situ, a lift-out of a lamella with a thickness of 1 μm (length 15 μm and height up to 10 μm) perpendicular to the rolling direction and a transfer to an Mo TEM grid (molybdenum TEM lattice) were carried out. This is followed by thinning with the FIB until the TEM lamella is completely translucent to electrons. For this purpose, both the acceleration voltage and the amperage of the FIB currents are successively reduced (from 30 kV to 10 kV and 5 kV; and from 300 pA stepwise to 10 pA). The final thickness was then set to smaller than 100 nm since the foil is not translucent otherwise. Diffraction images were recorded with a Philips CM200 TEM at 200 kV acceleration voltage.

Transmission electron microscope examinations were carried out on a double aberration-corrected FEI Titan3 Themis 80-300 at an acceleration voltage of 300 kV. The sample was mounted on a low-profile double-tilt holder from FEI, which inter alia enables energy-dispersive X-ray spectroscopy (EDXS) measurements with minimized scattered radiation. Solid-state detectors (silicon semiconductor detectors) which are arranged annularly and concentrically with respect to one another and integrally measure the signal of the scattered electrons in a particular scattering angle range are used for imaging in the STEM (scanning transmission electron microscopy) mode.

In the nanodiffraction mode, diffraction images are not generated under parallel illumination conditions, but rather the electron beam impinging on the sample is set to convergent (with a small convergence angle, here 0.36 mrad for half the convergence angle). The TEM (FEI Titan) used is equipped with a special condenser aperture from the Molecular Foundry nanoscience user facility at Lawrence Berkeley National Laboratory in Berkeley, Calif., USA, which condenser aperture was used for these measurements. As a result of the electron beam converging at a point of the sample, a diffraction image can be recorded from exactly this sample position. Due to the convergent beam, instead of diffraction points, disks with a corresponding angular diameter can then be seen in the diffraction image. Diffraction images were recorded with a Ceta camera (4096×4096 pixels CMOS sensor; physical pixel size 14×14 pm²; exposure time 12.5 to 1000 ms; selected resolution 512×512 to 2048×2048 pixels).

If a defined sample region is scanned under these conditions in the STEM mode, the selection of the STEM detectors and of the camera length can be used to precisely set which of these reflections (based on their diffraction angles) is to contribute to the image. In this case, it was possible, with a camera length of 115 or 145 mm, to isolate an inner ring of reflections which are not fundamental but exclusively superstructure reflections, using a DF2 detector (dark field detector, shaded by a DF4 detector). Only regions that have a superstructure with this diffraction reflection thus appear in these STEM images.

In order to additionally carry out energy-dispersive X-ray spectroscopy (EDXS) in the STEM mode, the X-ray detector system SuperXG2 was used, consisting of four detector segments, which are arranged all around above the sample in a relevant quadrant. The combination with STEM makes it possible to record a separate X-ray spectrum for each scanned pixel and thus to create element distribution maps. All four detector segments were activated for this recording, and the energy range of the detection was set to 20 keV with a dispersion of 5 eV. During the recording period of a total of approx. 125 min, 145 frames (resolution 780×642 pixels) were recorded, the recording duration per frame was 51.4 s for a dwell time per pixel of 100 ps. The data set was recorded under nanodiffraction conditions in order to enable a correlation with regions with a superstructure (bright in DF2).

The elemental concentrations in atom percent (at %) were quantified by means of an automatic spectrum fit, in which modeled element peaks and background signal are adapted to the measured spectrum. In this case, the default settings (lines/families) for each element were used and an empirical background correction was selected; the data were spatially pre-filtered prior to quantification with a 4-pixel average filter and post-filtered after quantification likewise with a 4-pixel average filter. All other settings were left at their default values.

For the quantification of the sample composition, the elements expected in the alloy (Cu, Ru, Pd, Ag) were selected. In order to deconvolute the measured spectrum, besides these elements, further elements that potentially cause artifacts in the spectrum but do not originate from the alloy itself were taken into account: organic contamination/oxidation (C, O); spacer rings (Al) used in the sample holder; material of the semiconductor detector (Si); components in the TEM column (Fe); ion implantation/material deposition during the FIB lamella preparation (Ga, Pt); TEM grid holding the lamella (Mo). These elements are thus taken into account in the spectrum fit but not in the calculation of the sample composition, where their concentration is assumed to be 0.

All TEM data was evaluated using Velox Software (version 3.3.0.885- 810c504366). This comprises the selection of image regions, measurements of distances in images, adjustment of brightness/contrast, quantification of element concentrations, and the export as 8/16-bit TIFF files, with data bars where applicable.

In addition, the software JEMS (Java Electron Microscopy Software, version 4.8330U2019b20) was used to simulate expected diffraction images of the B2 crystal structure and of ring patterns. For this purpose, a unit cell was first generated based on the B2 crystal structure, which fills atomic positions with Cu or Pd and sets a lattice parameter of a=0.2977 nm. Diffraction images thereof were generated in different zone axes with the “Draw diffraction pattern” function and compared to the experimental ones. A quantitative comparison based on the method of quotients took place in each case on the basis of two diffraction points in the experimental diffraction image and the corresponding points in the simulation. If the angles between the two points with respect to zero beam (always 90°) and the quotient of the distances to the zero beam match well, this indicates that the zone axes match.

A palladium-copper-silver alloy with the composition of 51.5% by weight of palladium, 36.5% by weight of copper, 10.5% by weight of silver, and 1.5% by weight of ruthenium (Pd51.5Cu36.5Ag10.5Ru1.5 alloy) was produced according to the aforementioned method and rolled to 20 μm to 100 μm. In addition, the alloys contain customary impurities with a concentration of less than 0.1% by weight. Subsequently, the alloy was stored at 380° C. for 4 minutes (SHT, short heat treatment), stored for 3 hours (LHT, long heat treatment), or solution-annealed and not stored at 380° C. (SA, solution annealing). Three different Pd51.5Cu36.5Ag10.5Ru1.5 alloys (SHT, LHT, SA) were examined, which differ by the duration of the tempering at 380° C., namely tempered for 4 minutes, 3 hours, and not at 380° C. In the Pd51.5Cu36.5Ag10.5Ru1.5 SA alloy not tempered at 380° C., a temperature of above 750° C. (in the present case at 900° C.) was thus used as the last temperature treatment.

The Pd51.5Cu36.5Ag10.5Ru1.5 SHT and LHT alloys produced in this way have an electrical conductivity of 27% IACS (15.7 * 106 S/m) and a hardness of 380 HV0.05.

### BRIEF DESCRIPTION OF THE DRAWINGS

Measurement results obtained on Pd-Cu-Ag alloys are explained below with reference to twelve figures. The figures show:

FIG. 1: an electron diffraction image with 265 mm camera length of a Pd51.5Cu36.5Ag10.5Ru1.5 SHT alloy, which was finally stored for 4 minutes at 380° C., wherein the diffraction reflections of the B2 crystal structure (CuPd) and of an fcc structure (Cu) to be expected at the corresponding angles are drawn as rings;

FIG. 2: an electron diffraction image with 265 mm of a Pd51.5Cu36.5Ag10.5Ru1.5 LHT alloy, which was finally stored for 3 hours at 380° C., wherein the diffraction reflections of the B2 crystal structure (CuPd) and of the fcc structure (Cu) to be expected at the corresponding angles are drawn as rings;

FIG. 3: an electron diffraction image with 1680 mm camera length of a Pd51.5Cu36.5Ag10.5Ru1.5 SA alloy, which was finally not annealed, is thus finally solution-annealed and has no B2 crystal structure, wherein the diffraction reflections of the fcc structure (Cu) to be expected at the corresponding angles are drawn in;

FIG. 4: an XRD analysis of the LHT and SA alloys according to FIGS. 2 and 3;

FIG. 5: a nanodiffraction image with convergent electron beam of a grain of the Pd51.5Cu36.5Ag10.5Ru1.5 LHT alloy according to FIG. 3 in the direction of the 203 zone axis, with lattice parameters determined therefrom;

FIG. 6: a nanodiffraction image with convergent electron beam of a grain of the Pd51.5Cu36.5Ag10.5Ru1.5 LHT alloy according to FIG. 3 in the direction of the 102 zone axis, with lattice parameters determined therefrom;

FIG. 7: an element distribution map, obtained by EDX mapping, of silver (Ag) of the Pd51.5Cu36.5Ag10.5Ru1.5 LHT alloy according to FIG. 3;

FIG. 8: an element distribution map, obtained by EDX mapping, of ruthenium (Ru) of the Pd51.5Cu36.5Ag10.5Ru1.5 LHT alloy in the same image section as FIG. 7;

FIG. 9: an element distribution map, obtained by EDX mapping, of palladium (Pd) of the Pd51.5Cu36.5Ag10.5Ru1.5 LHT alloy in the same image section as FIG. 7;

FIG. 10: an element distribution map, obtained by EDX mapping, of copper (Cu) of the Pd51.5Cu36.5Ag10.5Ru1.5 LHT alloy in the same image section as FIG. 7;

FIG. 11: an electron-microscopic STEM image over the region of the Pd51.5Cu36.5Ag10.5Ru1.5 LHT alloy that was scanned in FIGS. 7 to 10; and

FIG. 12: an XRD analysis of the LHT alloy according to FIG. 2 with the reflections characteristic of the B2 structure.

### DETAILED DESCRIPTION OF THE INVENTION

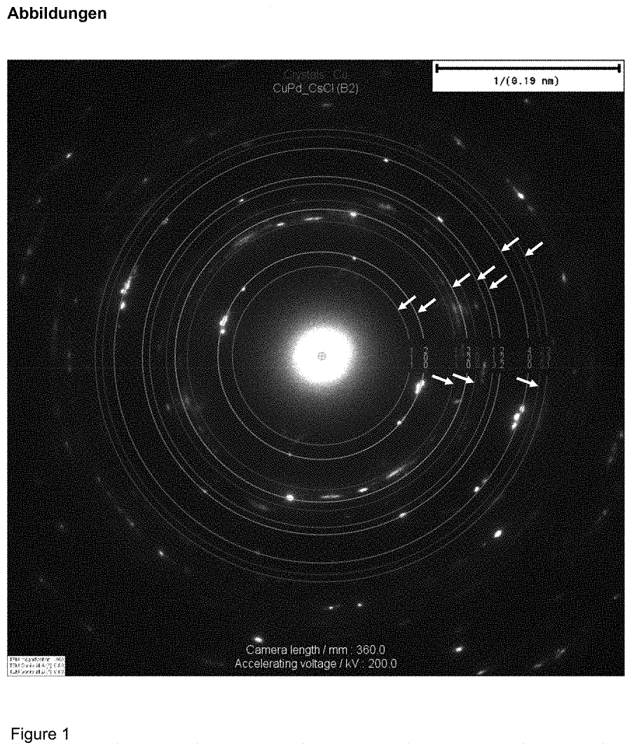

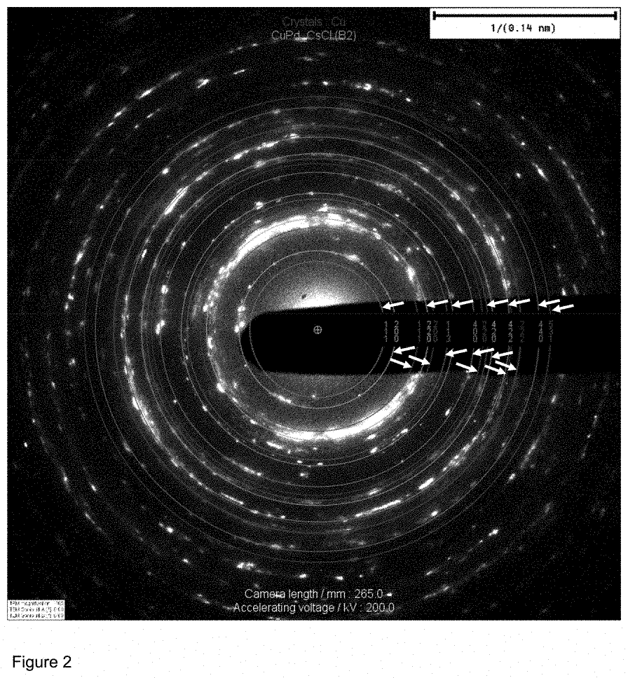

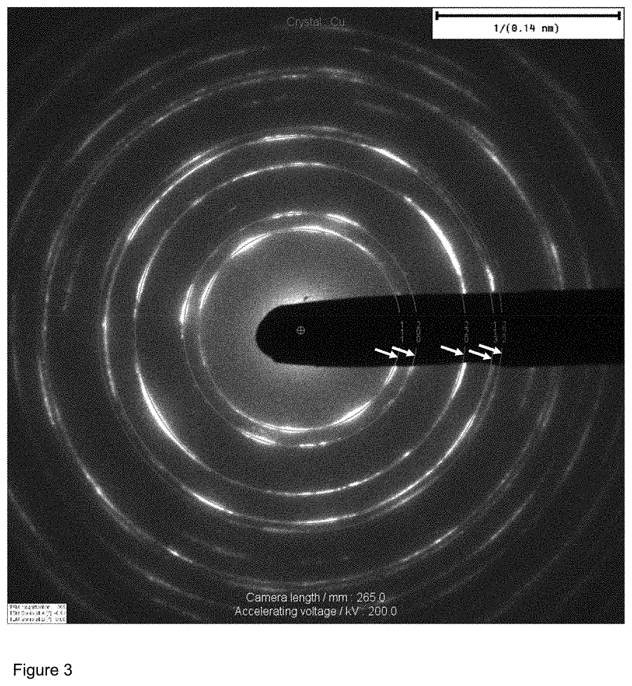

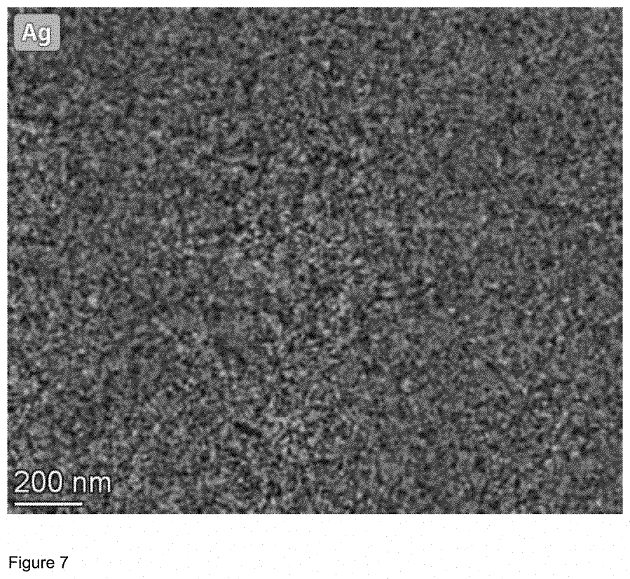

The reflections or rings of the electron diffraction images of the STEM examinations show that the B2 crystal structure forms in the two Pd51.5Cu36.5Ag10.5Ru1.5 SHT and LHT alloys (see FIGS. 1 and 2). The rings of the B2 crystal structure modeled with a B2 crystal structure (CuPd) are marked with white arrows pointing left. The rings of another structure assumed as fcc structure (Cu) and modeled are marked with white arrows pointing right. The B2 structure corresponds to the CsCl structure and, only for this reason, this generic designation (CsCl ) was used in FIGS. 1 and 2 in addition to CuPd. Of course, no CsCl is to be expected in the LHT and SHT alloys. In addition, only the designation CuPd was used for the modeling, even though it is a B2 crystal structure additionally containing silver and also a small amount of ruthenium besides copper and palladium, as could be subsequently confirmed by EDXS mapping (see FIGS. 7 to 10). The fcc structure was also modeled only with the structure of copper, and it is not pure copper. In the Pd51.5Cu36.5Ag10.5Ru1.5 SA alloy, on the other hand, no B2 crystal structure can be seen (see FIG. 3). Only the other structure assumed as the fcc structure (Cu) and modeled accordingly was found there. The rings of the fcc structure are marked in FIG. 3 with white arrows pointing right. The found rings of the SHT and LHT samples can be identified primarily by the rings calculated by the B2 crystal structure (see the white arrows pointing left), which can be seen most clearly in the Pd51.5Cu36.5Ag10.5Ru1.5 alloy (LHT), which was tempered for a long time (see FIG. 2).

Besides the B2 crystal structure, one or more other phases, in particular the phase assumed as the fcc structure, can also be seen in the Pd51.5Cu36.5Ag10.5Ru1.5 LHT alloy since some of the experimentally observed rings are not covered by the B2 crystal structure. The extrinsic phase could have a face-centered cubic structure (fcc). The rings that cannot be ascribed to the B2 crystal structure are all very weak so that only a small proportion of the other phase (possibly fcc) is present in the measured section.

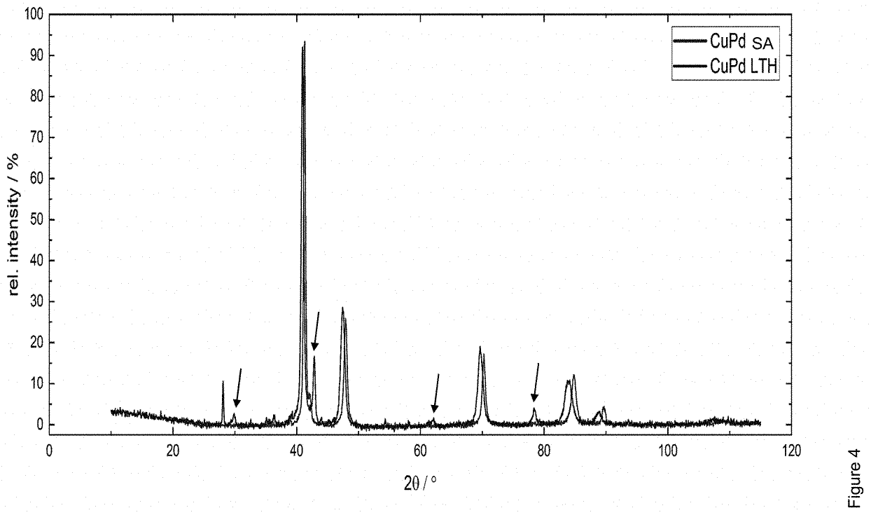

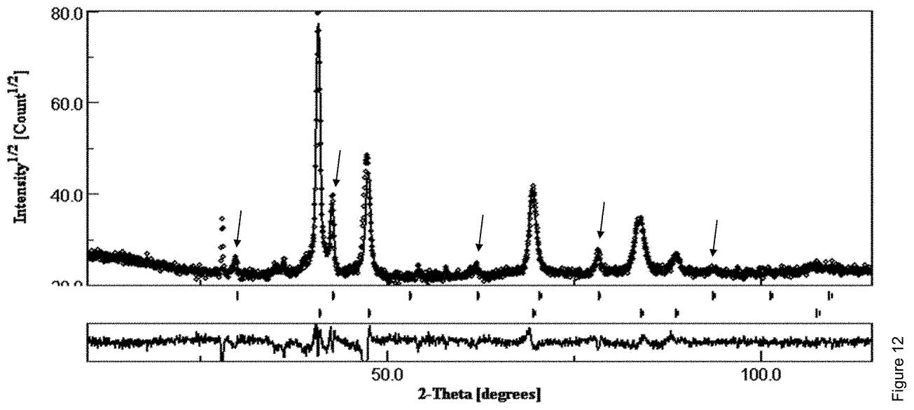

The B2 crystal structure in the Pd51.5Cu36.5Ag10.5Ru1.5 LHT alloy can also be seen in the XRD examinations according to FIG. 4 and FIG. 12 (the corresponding reflections are marked with arrows), while the Pd51.5Cu36.5Ag10.5Ru1.5 SA alloy does not show a B2 crystal structure (the reflections are missing completely there, see FIG. 4). FIG. 4 shows x-ray diffractograms of the Pd51.5Cu36.5Ag10.5Ru1.5 SA alloys (in FIG. 4, displaced to the right at slightly higher angles 2Θ) and LHT alloys (in FIG. 4, displaced to the right at slightly lower angles 2Θ). In the LHT alloy, proportions of an extrinsic phase with a face-centered cubic crystal structure can be seen as the main component. The SA alloy shows exclusively this face-centered cubic crystal structure. FIG. 12 shows the XRD image of the Pd51.5Cu36.5Ag10.5Ru1.5 LHT alloy isolated and shown with the reflections typical of the B2 crystal structure, wherein the reflections typical of the B2 crystal structure are marked by the arrows in FIG. 12. The reflections of the B2 crystal structure to be seen in FIG. 12 allow the conclusion that the proportion of the B2 crystal structure in the Pd51.5Cu36.5Ag10.5Ru1.5 LHT alloy is significantly greater than 1% by volume and is also greater than 5% by volume.

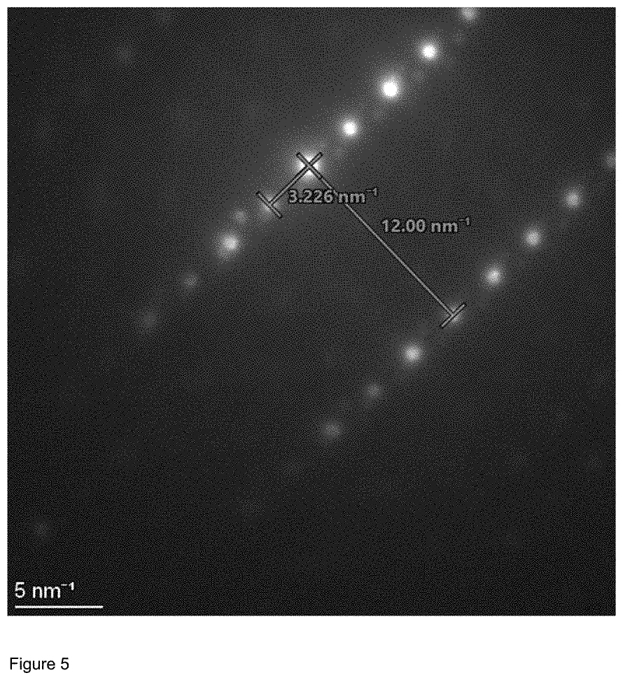

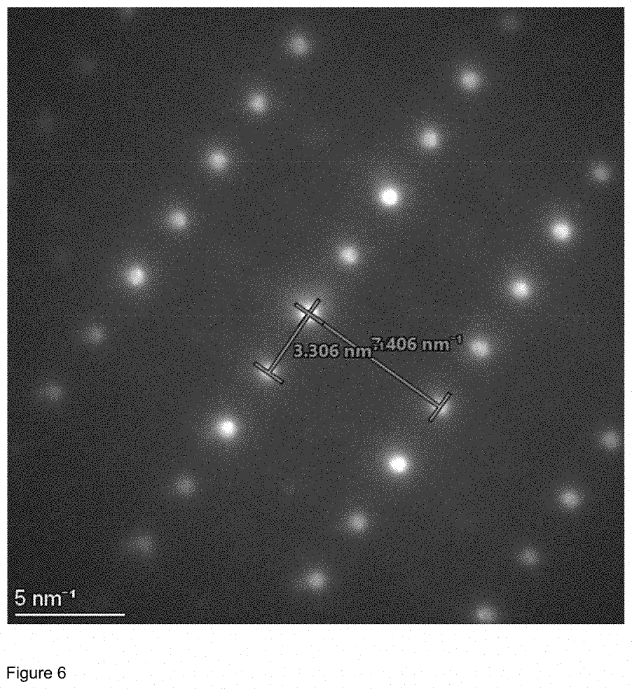

By means of TEM, grains of the B2 crystal structure in the Pd51.5Cu36.5Ag10.5Ru1.5 LHT alloys were measured with a convergent electron beam (see FIGS. 5 and 6, which show different zone axes of the crystal lattice of the B2 crystal structure). The diffraction patterns were recorded in different zone axes (ZA) in the bright regions of the STEM images, where the B2 crystal structure was expected. All electron diffraction images and the calculated lattice distances, which are drawn in in FIGS. 5 and 6, are consistent with the B2 crystal structure. This can be seen by comparing the experimental pattern to the relevant simulation based on the quotient method. Methods of this kind are known to the person skilled in the art from the literature (see, for example, “Werkstoffkunde Grundlagen Forschung Entwicklung” [“Materials Science, Basics, Research, Development” by Prof. Dr. Eckard Macherauch and Prof. Dr. Volkmar Gerold (Vieweg Verlag)-Vol. 1: “Einführung in die Elektronenmikroskopie Verfahren zur Untersuchung von Werkstoffen and anderen Festkörpern” [“Introduction to electron microscopy methods for examining materials and other solids”] by Manfred von Hemendahl (1970), Chapter 3.5. “Methode der Quotienten von Rₙ” [“Method of quotients of Rₙ”] (page 91 et seqq.) and “Cu—Pd (Copper-Palladium) P. R. Subramanian, D. E. Laughlin, Phase Diagram Evaluations: Section II, page 236, Table 7 “Lattice Parameters of Ordered CsCl-Type CuPd” by [39Jon] -->50.0% =0.2977, Journal of Phase Equilibria Vol. 12, No. 2, 1991). An exact calibration of the cathodoluminescence (CL) is not important here since only the ratio of two measured reciprocal distances is of interest here. The angle between all measured distance pairs is 90°. The absolute values of the lattice parameters are not relevant here, but only the ratio between the two lattice parameters of an image, since the camera length of the simulation (i.e., the “magnification”) was not calibrated 1:1. In addition, some rings appear slightly widened so that not all reflections lie exactly on the associated ring. This could potentially be caused by local internal stresses or variations in the composition.

By detecting multiple different zone axes of the B2 crystal structure, the presence of this B2 crystal structure in the sample could be detected and thus proven. In addition, a match with the XRD measurements is apparent. In order to clarify the origin of the different diffraction rings in the recorded ring pattern, the “Draw ring diffraction pattern” function in JEMS under “Crystal >Structure Factor” was used, and the radii of the individual rings to be expected are thus schematically placed over the ring pattern recorded in the TEM (see FIG. 2). In addition to the expected rings of the B2 crystal structure (a=0.2977 nm), the rings of a possible fcc matrix (a=0.365 nm for Cu) were taken into account here.

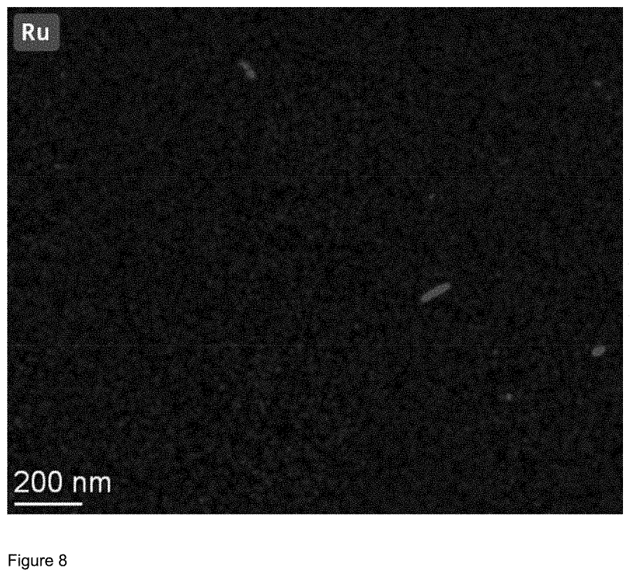

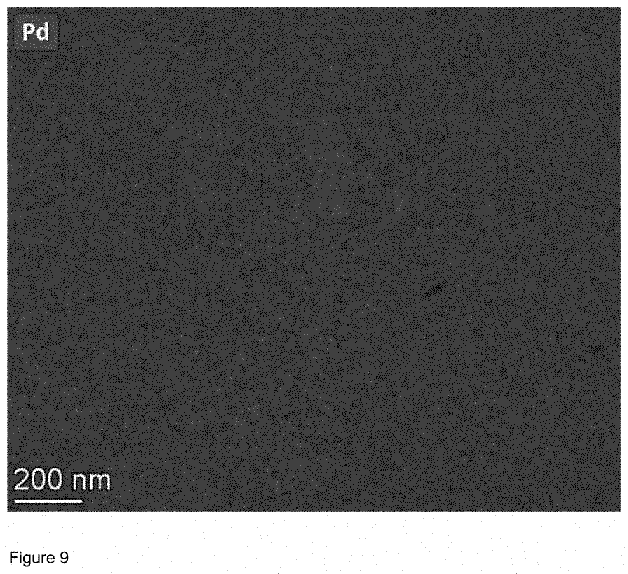

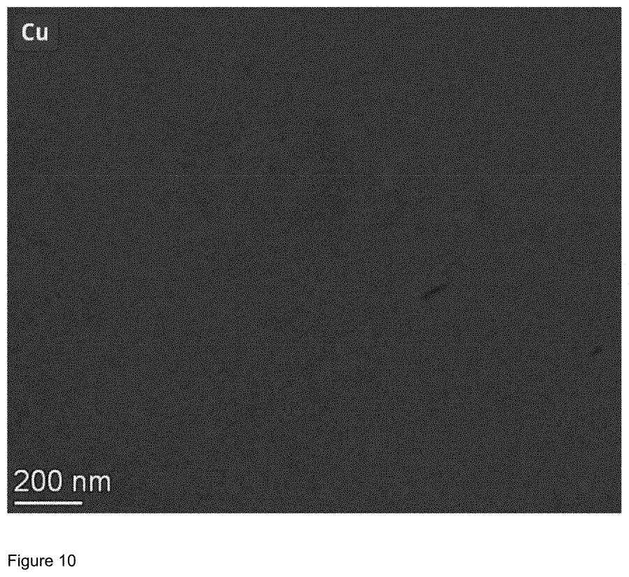

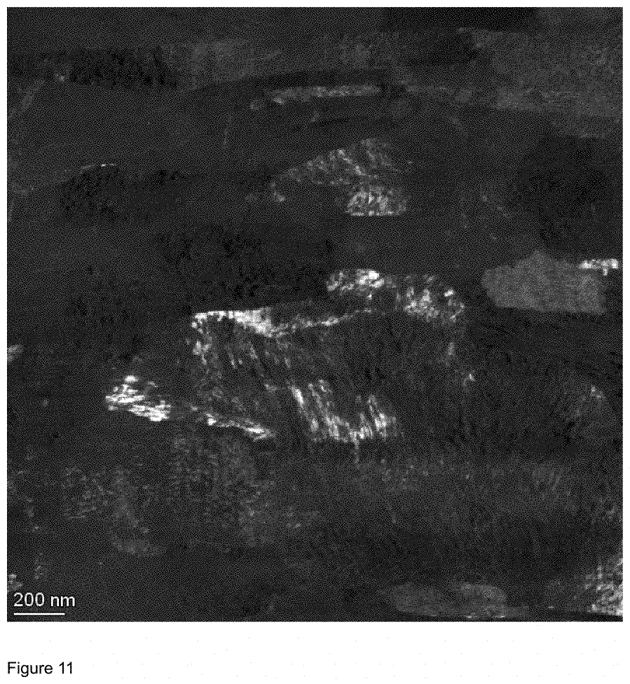

Furthermore, by means of EDXS mapping, the distribution of silver (FIG. 7), ruthenium (FIG. 8), palladium (FIG. 9), and copper (FIG. 10) in a cut surface through the Pd51.5Cu36.5Ag10.5Ru1.5 LHT alloy was determined. The relevant image section is shown in FIG. 11. It can be seen from the images that small amounts of ruthenium precipitates are present and the elements are otherwise largely identically distributed. In particular, the silver in the Pd51.5Cu36.5Ag10.5Ru1.5 alloy is uniformly distributed, which is surprising when starting from the examinations known from the prior art regarding the ternary phase diagram. As a result, a high electrical conductivity and a high breaking strength of the Pd51.5Cu36.5Ag10.5Ru1.5 alloy can be achieved.

In the measurements of the EDXS mapping, no precipitates of silver, palladium, or of binary silver-palladium compounds could be detected since the copper in the Pd51.5Cu36.5Ag10.5Ru1.5 LHT alloy can be detected over a wide area except in the ruthenium inclusions (see FIG. 10) and since the distribution of palladium and silver in the Pd51.5Cu36.5Ag10.5Ru1.5 LHT alloy outside of the ruthenium precipitates appears largely homogeneous (see FIGS. 7 and 9). This is surprising when starting from the examinations regarding the phase diagram in the prior art, which would suggest to expect a significant proportion of silver, palladium, or binary silver-palladium compounds of more than 10% by volume.

For the measurements of FIGS. 7 to 10, a SuperXG2 X-ray detector was used, wherein all 4 segments were used in an energy range of 20 kV with a dispersion 5 eV. The recording duration is about 125 minutes (145 frames, 780×642 pixels, dwell time 100 μs, recording duration per frame 51.4 s). The data set was recorded under nanodiffraction conditions in order to enable a correlation with regions with a superstructure (bright in DF2). The detector DF2 has a minimum diameter of 2.3 mm and a maximum diameter of 24 mm

Quantification settings: default settings (lines/families) for each element; empirical background correction; quantification in at %; pre-filtering with 4-pixel average filter; post-filtering with 4-pixel average filters; all other settings were left at their default values.

Since the (maximum measured) Ag concentration is lower in the Ag map (FIG. 7) than in the other elements, the gray scale ends at 17 atom %. The background noise is therefore better seen in FIG. 7 than in the other maps according to FIGS. 8, 9, and 10.

The examinations show that the B2 crystal structure in the Pd51.5Cu36.5Ag10.5Ru1.5 LHT alloy is contained in the examined LHT composition and no or only very small amounts (<1% by volume) of silver precipitates, palladium precipitates, or binary silver-palladium precipitates form in the Pd51.5Cu36.5Ag10.5Ru1.5 alloy. The proportion of the B2 crystal structure can be estimated by the intensity of the reflections caused by the B2 crystal structure in XRD, to at least 5% by volume of the total Pd51.5Cu36.5Ag10.5Ru1.5 LHT alloy. At least no silver precipitates, palladium precipitates, or binary palladium-silver precipitates in the Pd51.5Cu36.5Ag10.5Ru1.5 LHT alloy can be seen.

The features of the invention disclosed in the above description and in the claims, figures and exemplary embodiments, both individually and in any desired combination, can be essential for implementing the invention in its various embodiments.

1. A palladium-copper-silver alloy consisting of
(a) 40 to 58% by weight of palladium,
(b) 25 to 42% by weight of copper,
(c) 6 to 20% by weight of silver,
(d) optionally up to 6% by weight of at least one element selected from the group consisting of ruthenium, rhodium, and rhenium, and
(e) up to 1% by weight of impurities,
wherein the palladium-copper-silver alloy contains a crystalline phase with a B2 crystal structure, and
wherein the palladium-copper-silver alloy has 0% to 10% by volume of precipitates of silver, palladium, and binary silver-palladium compounds.

2. The palladium-copper-silver alloy according to claim 1, wherein the palladium-copper-silver alloy contains
(a) 41 to 56% by weight of palladium,
(b) 26 to 42% by weight of copper, and
(c) 7 to 19% by weight of silver,
preferably
(a) 41 to 56% by weight of palladium,
(b) 26 to 42% by weight of copper, and
(c) 8 to 18% by weight of silver,
more preferably
(a) 41 to 56% by weight of palladium,
(b) 26 to 42% by weight of copper, and
(c) 9 to 18% by weight of silver,
even more preferably
(a) 41 to 56% by weight of palladium,
(b) 26 to 42% by weight of copper, and
(c) 10 to 18% by weight of silver.

3. The palladium-copper-silver alloy according to claim 1, wherein the palladium-copper-silver alloy has a weight ratio of palladium to copper of at least 1.05 and at most 1.6 and a weight ratio of palladium to silver of at least 3 and at most 6.

4. The palladium-copper-silver alloy according to claim 1, wherein the palladium-copper-silver alloy contains at least 0.1% by weight of at least one element selected from the group consisting of ruthenium, rhodium, and rhenium.

5. The palladium-copper-silver alloy according to claim 1, wherein the palladium-copper-silver alloy contains precipitates of ruthenium, rhodium, rhenium, or a mixture of two of the elements selected from ruthenium, rhodium, and rhenium, or a mixture of ruthenium, rhodium, and rhenium, wherein preferably at least 90% by volume of the precipitates are arranged at grain boundaries of the palladium-copper-silver alloy, particularly preferably at least 99% by volume of the precipitates are arranged at grain boundaries of the palladium-copper-silver alloy.

6. The palladium-copper-silver alloy according to claim 1, wherein the palladium-copper-silver alloy contains up to 6% by weight of at least one element selected from the group consisting of ruthenium and rhodium, preferably from 0.1% by weight to 6% by weight of at least one element selected from the group consisting of ruthenium and rhodium, particularly preferably from 1% by weight to 6% by weight of at least one element selected from the group consisting of ruthenium and rhodium.

7. The palladium-copper-silver alloy according to claim 1, wherein the crystalline phase with the B2 crystal structure has a silver content of at least 6% by weight.

8. The palladium-copper-silver alloy according to claim 1, wherein the crystalline phase with the B2 crystal structure is obtained by quenching the palladium-copper-silver alloy after a temperature treatment, in particular after tempering, or after annealing, and/or the palladium-copper-silver alloy is shaped and hardened by multiple heat treatments and multiple rollings, wherein the heat treatments preferably take place at a temperature between 700° C. and 950° C. and quenching takes place after the heat treatment, wherein no melting of the palladium-copper-silver alloy takes place during the heat treatment, and/or the palladium-copper-silver alloy is produced by melting metallurgy and is subsequently hardened by rolling and tempering, wherein the palladium-copper-silver alloy preferably has a hardness of at least 380 HV0.05.

9. The palladium-copper-silver alloy according to claim 1, wherein the palladium-copper-silver alloy has a mean grain size of at most 2 μm.

10. The palladium-copper-silver alloy according to claim 1, wherein the palladium-copper-silver alloy has from 0% to 5% by volume of precipitates of silver, palladium, and/or binary silver-palladium compounds, preferably from 0% to 2% by volume of precipitates of silver, palladium, and/or binary silver-palladium compounds, particularly preferably from 0% to 1% by volume of precipitates of silver, palladium, and/or binary silver-palladium compounds, more particularly preferably no precipitates of silver, palladium, and/or binary silver-palladium compounds.

11. A molded body consisting of a palladium-copper-silver alloy according to claim 1, wherein the molded body preferably has the shape of a general cylinder with any base or of a coil-like general cylinder with any base, wherein particularly preferably, the height of the general cylinder is greater than all dimensions of the base of the general cylinder, wherein more particularly preferably, a minimum cross section of the base is at most 500 μm and a maximum cross section of the base is at most 10 mm.

12. A probe needle or a sliding contact wire consisting of a palladium-copper-silver alloy according to claim 1, wherein the probe needle or the sliding contact wire preferably has, at least in sections, the shape of a general cylinder with any base or of a curved general cylinder with any base, wherein particularly preferably, a minimum cross section of the base is at most 500 μm and a maximum cross section of the base is at most 10 mm, and/or the probe needle is attached to a card and electrically contacted at one end and the other end is mounted in a freely floating manner, or the sliding contact wire is attached to an electrical contact and electrically contacted at one end and the other end is mounted in a freely floating manner.

13. A use of a palladium-copper-silver alloy according to claim 1 for testing electrical contacts or for electrical contacting or for producing a sliding contact.

14. A method for producing a palladium-copper-silver alloy, wherein the chronological steps of:
A) optionally prealloying palladium with at least one of the elements selected from the list of ruthenium, rhodium, and rhenium, with a molar ratio of palladium to the at least one element selected from the list of ruthenium, rhodium, and rhenium of at least 3:1, by melting to produce a palladium prealloy;
B) alloying palladium or the palladium prealloy with copper and silver by melting and solidification in vacuo and/or under a protective gas, wherein at least 40% by weight and at most 58% by weight of palladium or at least 40% by weight and at most 64% by weight of palladium prealloy, at least 25% by weight and at most 42% by weight of copper and at least 6% by weight and at most 20% by weight of silver are weighed out;
C) repeated processing by annealing at a temperature of more than 750° C. for at least 10 minutes and subsequent quenching and subsequent rolling;
D) rolling to achieve a final thickness of at most 100 μm;
E) final annealing at a temperature between 250° C. and 600° C. for a period of at least 1 minute.

15. The method according to claim 14, wherein
in step B), a weight ratio of palladium to copper of at least 1.05 and at most 1.6 and a weight ratio of palladium to silver of at least 3 and at most 6 are weighed out, and/or
in step B), the melting takes place by induction melting or by vacuum induction melting, and/or
in step B), a noble gas, in particular argon, is used as protective gas, preferably at a partial pressure between 10 mbar and 100 mbar, and/or
in step B), the solidification is carried out by casting in a copper permanent mold, in particular in an uncooled copper permanent mold, wherein the temperature of the melt before casting is preferably less than 100° C. above the melting temperature of the palladium-copper-silver alloy.

16. The method according to claim 14, wherein
in step C), the quenching is carried out in water, and/or
in step C), the annealing is carried out at a temperature between 850° C. and 950° C., preferably at a temperature of 900° C., and/or
in step E), the final annealing takes place at a temperature between 300° C. and 450° C., preferably at a temperature between 360° C. and 400° C.
